(19) United States
(12) Patent Application Publication
(10) Pub. No.: US 2025/0239516 A1
(43) Pub. Date: Jul. 24, 2025

(54) SEMICONDUCTOR DEVICE AND METHOD OF MANUFACTURING SEMICONDUCTOR DEVICE

(71) Applicant: Mitsubishi Electric Corporation, Tokyo (JP)

(72) Inventor: Kana ISERI, Tokyo (JP)

(73) Assignee: Mitsubishi Electric Corporation, Tokyo (JP)

(21) Appl. No.: 18/954,462

(22) Filed: Nov. 20, 2024

(30) Foreign Application Priority Data
Jan. 24, 2024 (JP) 2024-008857

(51) Int. Cl. H01L 23/498; H01L 23/00; H01L 23/31; H01L 29/16

(52) U.S. Cl. CPC H01L 23/49838; H01L 23/3121; H01L 24/11; H01L 24/13; H10D 62/8325; H01L 2224/11013; H01L 2224/13022; H01L 2924/3512

(57) ABSTRACT

An object is to provide a semiconductor device and a method of manufacturing the semiconductor device which can reduce occurrence of a triple point of three layers of a plating layer, a resin layer, and a solder layer on an electrode layer, and prevent a split in the electrode layer. A semiconductor device is sealed by a sealing resin, and the semiconductor device includes: a semiconductor substrate; an electrode layer on an upper surface of the semiconductor substrate; a plating layer on an upper surface of the electrode layer, the plating layer including a first region, and a second region outside of the first region in a plan view; a solder layer on the first region of the plating layer; and a solder blocking portion on the plating layer, the solder blocking portion blocking solder from flowing on the second region from above the first region.

### BACKGROUND OF THE INVENTION

### Field of the Invention

The present disclosure relates to a semiconductor device and a method of manufacturing the semiconductor device.

### Description of the Background Art

Japanese Patent Application Laid-Open No. 2022-178755 discloses a semiconductor module including a semiconductor chip including a semiconductor substrate and an electrode layer formed on the semiconductor substrate, a plating layer formed on the electrode layer, a solder layer formed on the plating layer, and a sealing resin sealing the semiconductor chip. Furthermore, this application describes a structure in which the entire side surface of the plating layer is covered with the solder layer.

In the semiconductor device described in the aforementioned application, a triple point at which three layers of the plating layer, a resin layer, and the solder layer meet exists on the electrode layer. Thus, a distortion concentrates on a triple point portion due to a difference in stress between the three layers. This causes a problem of a split in the electrode layer.

The present disclosure has been conceived to solve the problem, and has an object of providing a semiconductor device and a method of manufacturing the semiconductor device which can reduce occurrence of the triple point of the three layers of the plating layer, the resin layer, and the solder layer on the electrode layer, and prevent a split in the electrode layer.

### SUMMARY

An object of the present disclosure is to provide a semiconductor device and a method of manufacturing the semiconductor device which can reduce occurrence of a triple point of three layers of a plating layer, a resin layer, and a solder layer on an electrode layer, and prevent a split in the electrode layer.

A semiconductor device according to the present disclosure is a semiconductor device sealed by a sealing resin, and the semiconductor device includes: a semiconductor substrate; an electrode layer disposed on an upper surface of the semiconductor substrate; a plating layer disposed on an upper surface of the electrode layer, the plating layer including a first region, and a second region outside of the first region in a plan view; a solder layer disposed on the first region of the plating layer; and a solder blocking portion formed on the plating layer, the solder blocking portion blocking solder from flowing on the second region from above the first region.

A method of manufacturing a semiconductor device according to the present disclosure is a method of manufacturing a semiconductor device sealed by a sealing resin, and the method includes: an electrode layer formation step of forming an electrode layer on an upper surface of a semiconductor substrate; a plating layer formation step of forming a plating layer on an upper surface of the electrode layer, the plating layer including a first region, and a second region outside of the first region in a plan view; a solder blocking portion formation step of forming a solder blocking portion in the plating layer, the solder blocking portion blocking solder from flowing on the second region from above the first region; and a solder layer formation step of supplying the solder onto the first region to form a solder layer.

The semiconductor device and the method of manufacturing the semiconductor device according to the present disclosure can reduce occurrence of a triple point of three layers of a plating layer, a resin layer, and a solder layer on an electrode layer, and prevent a split in the electrode layer.

These and other objects, features, aspects, and advantages of the present invention will become more apparent from the following detailed description of the present invention when taken in conjunction with the accompanying drawings.

### BRIEF DESCRIPTION OF THE DRAWINGS

FIG. 1 is a schematic top view of a semiconductor device according to Embodiment 1;

FIG. 2 is a schematic cross-sectional view taken along X-X in FIG. 1 of the semiconductor device according to Embodiment 1;

FIG. 3 is a schematic plan view taken along Y-Y in FIG. 2 of the semiconductor device according to Embodiment 1;

FIG. 4 is a schematic plan view of a semiconductor device according to Modification 1 of Embodiment 1;

FIG. 5 is a schematic cross-sectional view taken along X-X in FIG. 4 of the semiconductor device according to Modification 1 of Embodiment 1;

FIG. 6 is a schematic cross-sectional view of a semiconductor device according to Modification 2 of Embodiment 1;

FIG. 7 is a schematic plan view of a semiconductor device according to Modification 3 of Embodiment 1;

FIG. 8 is a schematic plan view of a semiconductor device according to Modification 3 of Embodiment 1;

FIG. 9 is a schematic plan view of a semiconductor device according to Modification 4 of Embodiment 1;

FIG. 10 is a schematic cross-sectional view taken along X-X in FIG. 9 of the semiconductor device according to Modification 4 of Embodiment 1;

FIG. 11 is a schematic plan view of a semiconductor device according to a modification of Embodiment 1;

FIG. 12 is a schematic plan view of a semiconductor device according to a modification of Embodiment 1;

FIG. 13 is a schematic plan view of a semiconductor device according to Embodiment 2;

FIG. 14 is a schematic cross-sectional view taken along X-X in FIG. 13 of the semiconductor device according to Embodiment 2;

FIG. 15 is a schematic plan view of a semiconductor device according to Modification 1 of Embodiment 2;

FIG. 16 is a schematic cross-sectional view taken along X-X in FIG. 15 of the semiconductor device according to Modification 1 of Embodiment 2;

FIG. 17 is a schematic cross-sectional view of a semiconductor device according to Modification 2 of Embodiment 2;

FIG. 18 is a schematic plan view of a semiconductor device according to Modification 3 of Embodiment 2; and

FIG. 19 is a schematic plan view of a semiconductor device according to Modification 3 of Embodiment 2.

### DESCRIPTION OF THE PREFERRED EMBODIMENTS

### Introduction

One side in a direction parallel to a depth direction of a semiconductor device will be referred to as “upper”, and the other side will be referred to as “lower”. One of two main surfaces of a substrate, a layer, or another component will be referred to as an “upper surface”, and the other surface will be referred to as a “lower surface”. The directions of “up” and “down” are not limited to the direction of gravity or the direction when the semiconductor device is mounted.

For convenience of the description, a width direction of a semiconductor device will be described as an X direction, a depth direction of the semiconductor device which is orthogonal to the X direction will be described as a Y direction, and a thickness direction or a depth direction of the semiconductor device, that is, a direction normal to an XY plane will be described as a Z direction.

Since the drawings are schematically illustrated, the mutual relationships in size and position between images in different drawings are not necessarily accurate but may be appropriately changed. In the following description, the same reference numerals are assigned to the same constituent elements, and their names and functions are the same.

Thus, the detailed description thereof may be omitted.

### Embodiment 1

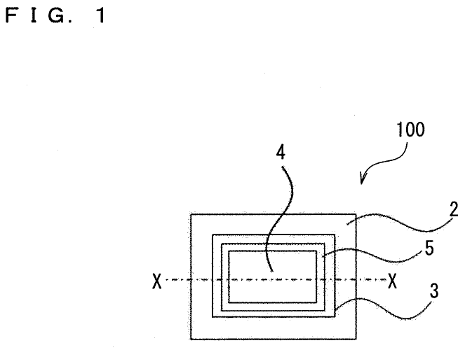

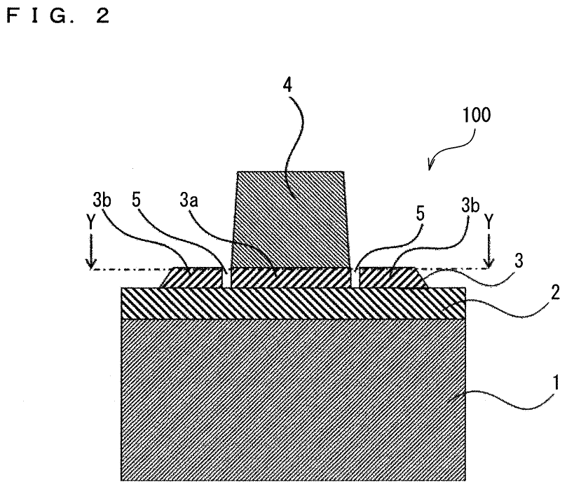

Hereinafter, Embodiment 1 will be described with reference to drawings. FIG. 1 is a schematic top view of a semiconductor device 100 according to Embodiment 1. FIG. 2 is a schematic cross-sectional view of the semiconductor device 100 according to Embodiment 1. FIG. 2 illustrates a cross section taken along an alternate long and short dashed line X-X in FIG. 1.

The semiconductor device sealed by a sealing resin, and a semiconductor device assumed to be sealed by a sealing resin in the future will be described in the following description.

The structure of the semiconductor device 100 will be described with reference to FIGS. 1 to 3. As illustrated in FIG. 2, the semiconductor device 100 includes a semiconductor substrate 1, an electrode layer 2, a plating layer 3, a solder layer 4, and a solder blocking portion 5.

The semiconductor substrate 1 contains, for example, various semiconductor materials including silicon (Si), silicon carbide (SiC), and gallium nitride (GaN).

As illustrated in FIG. 2, the electrode layer 2 is disposed on the upper surface of the semiconductor substrate 1. An interlayer insulating film to be described later may be disposed between the electrode layer 2 and the semiconductor substrate 1. The electrode layer 2 may be made of an aluminum alloy. The electrode layer 2 is made of, for example, an alloy of aluminum and silicon (an Al—Si based alloy).

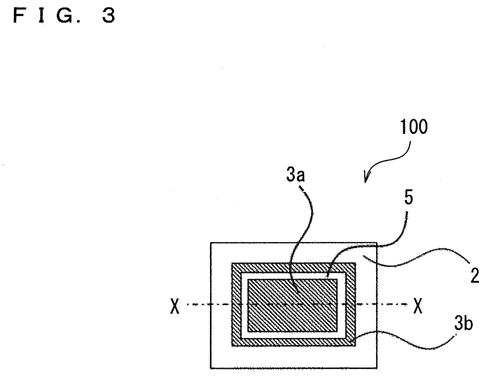

As illustrated in FIG. 2, the plating layer 3 is disposed on the upper surface of the electrode layer 2. Next, the plating layer 3 will be described more in detail with reference to FIG. 3. FIG. 3 is a horizontal cross section taken along an alternate long and short dashed line Y-Y in FIG. 2. In other words, FIG. 3 is a horizontal cross section with the upper surface of the plating layer 3 as a cross section, and omits the illustration of the solder layer 4. The aforementioned horizontal cross section will be referred to as a plan view. In the following description, the “plan view” is a horizontal cross section with the upper surface of the plating layer 3 of the semiconductor device as a cross section, similarly to FIG. 3. As illustrated in FIG. 3, the plating layer 3 includes a first region 3a located in the center of the plating layer 3, and a second region 3b located outside of the first region 3a in a plan view. Here, the plan view is a view seen from a point of view in FIG. 3. In the following description of this disclosure, the “plan view” is a view when the upper surface of the plating layer 3 of the semiconductor device is seen from the top as a cross section as illustrated in FIG. 3. The plating layer 3 may be made of, for example, Au, nickel, or a nickel alloy. The plating layer 3 may have, for example, a laminated structure including metal layers of two or more kinds. The laminated structure includes, for example, a NiP layer and an Au layer. The plating layer 3 improves the wettability between the electrode layer 2 and the solder layer 4 that is a bonding material, and can enhance the bondability with, for example, a lead frame.

As illustrated in FIGS. 1 to 3, the solder layer 4 is disposed on the first region 3a of the plating layer 3. Although the solder layer 4 is disposed across the entire upper surface of the first region 3a in Embodiment 1, the solder layer 4 may be formed on a part of the upper surface of the first region 3a.

As illustrated in FIGS. 2 and 3, the solder blocking portion 5 is formed in the plating layer 3. The solder blocking portion 5 is a space between the first region 3a and the second region 3b of the plating layer 3 in Embodiment 1. As illustrated in FIG. 3, the space may be formed to surround an outer periphery of the first region 3a of the plating layer 3. Although FIGS. 2 and 3 emphasize the width of the space more than the actual one, the width of the space may be a width of a crack that splits the plating layer 3 into the first region 3a and the second region 3b, which will be described later. As illustrated in FIG. 2, the side surface of the first region 3a of the side surfaces of the first region 3a and the second region 3b that form the space is preferably vertical to the upper surface of the electrode layer 2. The reason will be described later. As illustrated in FIG. 2, the space may be formed to reach the lower surface of the plating layer 3 from the upper surface of the plating layer 3. The space should be formed on the upper surface of the plating layer 3, and need not reach the lower surface of the plating layer 3.

As illustrated in FIG. 3, the space is preferably formed such that the center of the first region 3a matches the center of the plating layer 3. Although the space is symmetrically formed with respect to the center of the entire plating layer 3 in FIG. 3, the space need not be symmetrically formed. The space has only to be formed between the first region 3a and the second region 3b, and the formation position and the shape of the space may be any.

The semiconductor device 100 in Embodiment 1 is structured in the aforementioned manner. The structure of the plating layer 3 with the space that is the solder blocking portion 5 can reduce occurrence of the triple point of the three layers of the plating layer 3, the resin layer, and the solder layer 4 on the electrode layer 2, and prevent a split in the electrode layer 2. This reason will be hereinafter described.

Forming the space can block solder supplied onto the first region 3a from flowing on the second region 3b from above the first region 3a. The surface tension of the solder can retain the solder on the first region 3a and prevent the solder from flowing on the second region 3b and the electrode layer 2. Moreover, adjusting the width of the space in consideration of, for example, the viscosity of the solder can prevent the solder from entering the space. Thus, even when the semiconductor device 100 is sealed by a sealing resin, it is possible to reduce occurrence of the triple point of the three layers of the plating layer 3, a resin layer containing the sealing resin, and the solder layer 4 on the electrode layer 2. This can prevent a split in the electrode layer 2. When the split occurring in the electrode layer 2 reaches an interlayer insulating film 7, the interlayer insulating film 7 cannot function as an insulating film, and elements will be destroyed. Application of the present disclosure can prevent a split caused by the triple point on the electrode layer 2, and prevent the elements from being destroyed.

The width of the space as the solder blocking portion 5 is preferably narrower. Forming the width of the space narrower can prevent the solder from flowing into the space and flowing on the electrode layer 2. Furthermore, the side surface of the first region 3a of the side surfaces of the first region 3a and the second region 3b that form the space is preferably vertical to the upper surface of the electrode layer 2. When the plating layer 3 is normally formed on the electrode layer 2, the end of the plating layer 3 has a smooth shape with respect to the electrode layer 2. When the end has a smooth shape, the solder tends to flow on the electrode layer 2. Here, forming the side surface of the first region 3a that forms the space vertical to the upper surface of the electrode layer 2 can further prevent the solder from flowing into the space and flowing on the electrode layer 2.

When the semiconductor substrate 1 is made of SiC, the semiconductor substrate 1 has a breakdown voltage higher than that of a semiconductor substrate made of Si. Thus, a higher voltage is applied when the semiconductor device is used. Thus, a split more likely occurs in the electrode layer 2 in the SiC substrate. Application of the present disclosure can prevent a split caused by the triple point on the electrode layer 2, and prevent a split in the electrode layer 2.

When the electrode layer 2 is made of an aluminum alloy, for example, an Al—Si based alloy, the strength of the electrode layer 2 is relatively lower than the electrode layer 2 made of other materials. Thus, a split more likely occurs in the electrode layer 2. Application of the present disclosure can prevent a split caused by the triple point on the electrode layer 2 when the electrode layer 2 is made of an aluminum alloy that easily causes a split.

Next, a method of manufacturing the semiconductor device 100 according to Embodiment 1 will be described. Since the method of manufacturing the semiconductor device 100 according to Embodiment 1 is basically identical to a conventional method of manufacturing a semiconductor device, except a solder blocking portion formation step, the description of a part of the method will be omitted.

The method of manufacturing the semiconductor device 100 includes an electrode layer formation step, a plating layer formation step, the solder blocking portion formation step, and a solder layer formation step.

First, the electrode layer formation step will be described. The semiconductor substrate 1 is formed, and the electrode layer 2 is formed on the upper surface of the semiconductor substrate 1. The electrode layer 2 may be formed by a PVD process such as sputtering or vapor deposition.

Next, the plating layer formation step will be described. The plating layer 3 including the first region 3a and the second region 3b outside of the first region 3a in a plan view is formed on the upper surface of the electrode layer 2. The plating layer 3 may be formed by electroless plating or electroplating.

Next, the solder blocking portion formation step will be described. Embodiment 1 will describe a method of forming a space between the first region 3a and the second region 3b of the plating layer 3, using the solder blocking portion 5 as the space.

Passing a current and forming the space by splitting the plating layer 3 into the first region 3a and the second region 3b are preferable as an example method of forming the space. For example, the plating layer 3 may be split by allowing a main current larger than a normal main current to flow between a top electrode and a lower electrode included in the semiconductor device. Forming the space in the aforementioned method can make the width of the space a width of a crack that splits the plating layer 3 into the first region 3a and the second region 3b, and can form the side surface of the first region 3a that forms the space vertical to the upper surface of the electrode layer 2.

Thus, forming the space by splitting the plating layer 3 into the first region 3a and the second region 3b can narrow the width of the space, and can form the side surface of the first region 3a that forms the space vertical to the upper surface of the electrode layer 2. The method of forming the space is not limited to the method using a current. The space may be formed by, for example, forming a groove in the plating layer 3 by grinding or etching.

Next, the solder layer formation step will be described. Solder is supplied onto the first region 3a of the plating layer 3 to form the solder layer 4.

The aforementioned steps fabricate the semiconductor device 100. As described above, the method of manufacturing the semiconductor device 100 according to Embodiment 1 further includes the solder blocking portion formation step, and the solder blocking portion 5 is a space. Forming the space can block the solder supplied onto the first region 3a from flowing on the second region 3b from above the first region 3a in the solder layer formation step. The surface tension of solder can retain the solder on the first region 3a, and prevent the solder from flowing on the second region 3b and the electrode layer 2. Moreover, adjusting the width of the space in consideration of, for example, the viscosity of the solder can prevent the solder from entering the space. Thus, even when the semiconductor device 100 is sealed by a sealing resin, it is possible to reduce occurrence of the triple point of the three layers of the plating layer 3, the resin layer containing the sealing resin, and the solder layer 4 on the electrode layer 2. This can prevent a split in the electrode layer 2.

Forming the width of the space narrower can further prevent the solder from flowing into the space and flowing on the electrode layer 2. In addition, forming the side surface of the first region 3a that forms the space vertical to the upper surface of the electrode layer 2 can further prevent the solder from flowing into the space and flowing on the electrode layer 2.

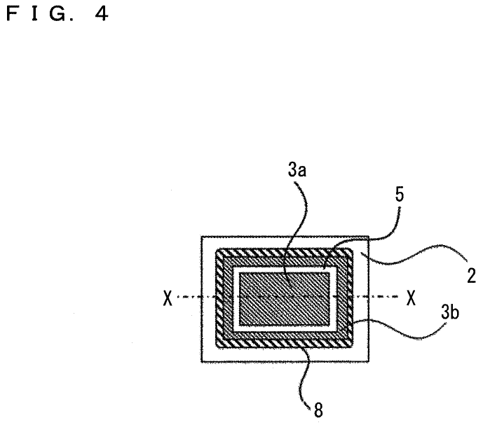

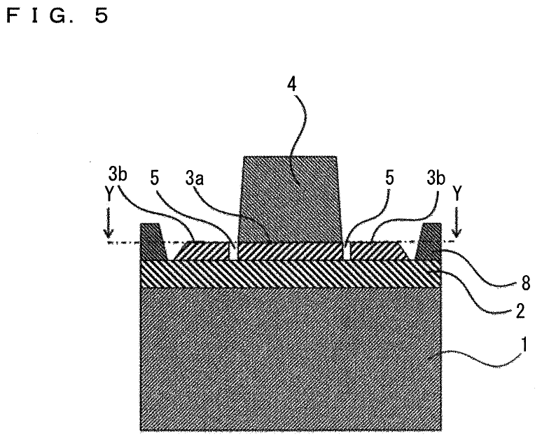

Next, modifications of Embodiment 1 will be described with reference to FIGS. 4 to 12. FIGS. 4 to 12 emphasize the width of the space more than the actual one. First, Modification 1 will be described with reference to FIGS. 4 and 5. FIG. 4 is a schematic plan view of a semiconductor device according to Modification 1. FIG. 5 is a schematic cross-sectional view of the semiconductor device according to Modification 1. FIG. 5 illustrates a cross section taken along an alternate long and short dashed line X-X in FIG. 4.

As illustrated in FIGS. 4 and 5, a protective film 8 may be further formed on the upper surface of the electrode layer 2 to surround an outer periphery of the plating layer 3. As illustrated in FIG. 5, the protective film 8 may be in contact with the upper surface of the electrode layer 2. As illustrated in FIG. 4, the protective film 8 may be formed to surround an outer periphery of the second region 3b of the plating layer 3. The protective film 8 may be made of, for example, polyimide.

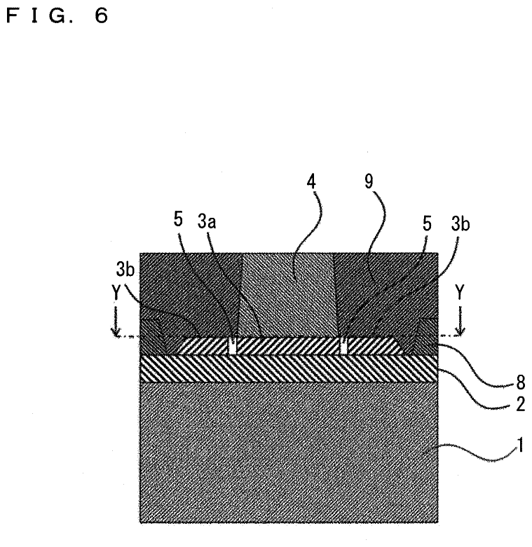

Next, Modification 2 will be described with reference to FIG. 6. FIG. 6 is a schematic cross-sectional view of a semiconductor device according to Modification 2. Modification 2 assumes that a semiconductor device is sealed by a sealing resin. As illustrated in FIG. 6, a sealing resin 9 for sealing at least the electrode layer 2 may be formed. As illustrated in FIG. 6, the sealing resin 9 need not be charged into the space. As described above, FIG. 6 emphasizes the width of the space, and the actual width of the space is narrow. Forming the width of the space narrower can prevent the sealing resin 9 as well as solder from entering the space. Voids may be formed in the space. Preventing solder and the sealing resin 9 from entering the space can form voids in the space. Since forming voids blocks solder on the first region 3a from entering the space, occurrence of the triple point on the electrode layer 2 can be further reduced. For example, optimizing a viscosity, a material, or a sealing process of the sealing resin can prevent the sealing resin 9 from entering the space. The sealing resin 9 may be charged into the space. Since charging the sealing resin 9 into the space blocks solder on the first region 3a from entering the space, occurrence of the triple point on the electrode layer 2 can be further reduced.

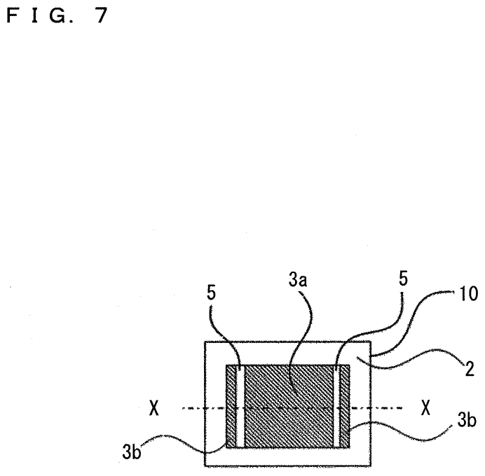

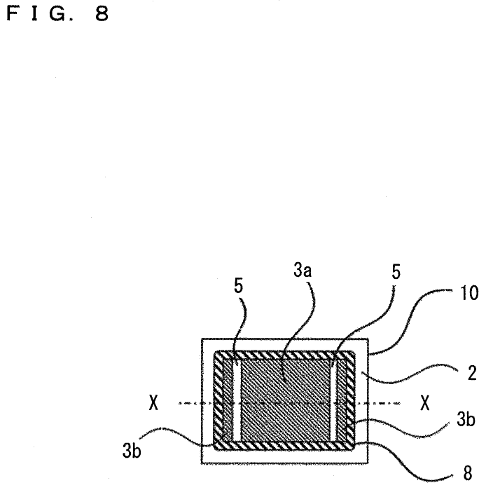

Next, Modification 3 will be described with reference to FIGS. 7 and 8. FIGS. 7 and 8 are schematic plan views of a semiconductor device according to Modification 3. The cross-sectional view taken along an alternate long and short dashed line X-X in FIG. 7 is identical to that in FIG. 2. The cross-sectional view taken along an alternate long and short dashed line X-X in FIG. 8 is identical to that in FIG. 5. A semiconductor chip 10 includes the semiconductor substrate 1 and the electrode layer 2. As illustrated in FIG. 7, when the semiconductor chip 10 is rectangular in a plan view, spaces may be formed only in regions of the plating layer 3 which are located on the short sides of the semiconductor chip 10. When the semiconductor chip 10 is rectangular, it is known that allowing solder to flow through the short sides of the semiconductor chip 10 more than long sides of the semiconductor chip 10 tends to cause splits in the electrode layer 2. Here, forming spaces only in regions of the plating layer 3 which are located on the short sides of the semiconductor chip 10 can reduce occurrence of the triple point on the electrode layer 2 on the short sides of the semiconductor chip 10 where splits easily occur, and can prevent a split in the electrode layer 2. Moreover, the structure of Modification 3 can increase the area of the first region 3a more than that of the structure according to Embodiment 1. This can widen a region on which solder is mounted, and improve the bonding strength.

As illustrated in FIG. 8, the protective film 8 may be formed in addition to the structure of Modification 3, similarly to Modification 1. As illustrated in FIG. 8, the protective film 8 may be formed to surround an outer periphery of the entire plating layer 3 including spaces.

Furthermore, the sealing resin 9 may be formed in addition to the structure of Modification 3, similarly to Modification 2.

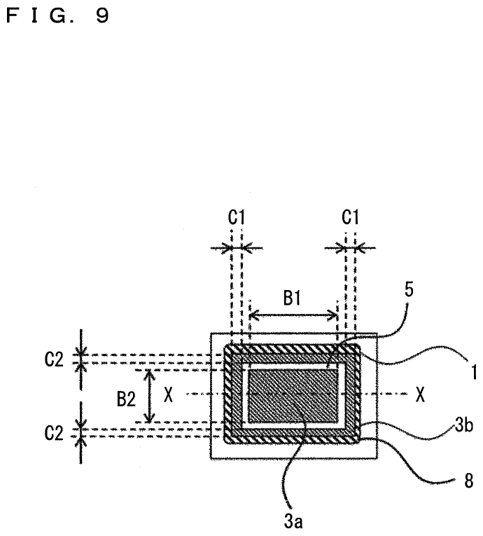

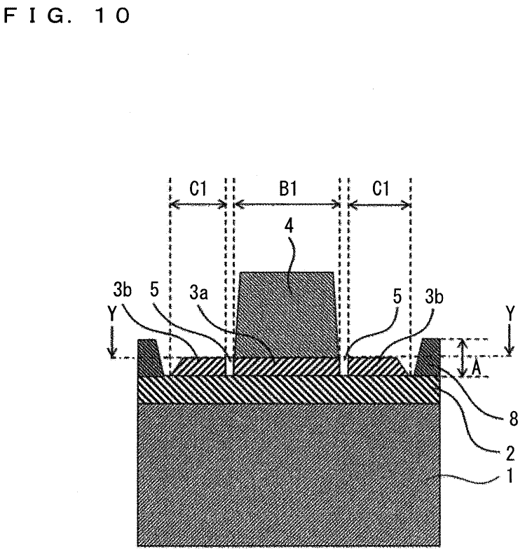

Next, Modification 4 will be described with reference to FIGS. 9 and 10. FIG. 9 is a schematic plan view of a semiconductor device according to Modification 4. FIG. 10 is a schematic cross-sectional view of the semiconductor device according to Modification 4. FIG. 10 illustrates a cross section taken along an alternate long and short dashed line X-X in FIG. 9. As illustrated in FIGS. 9 and 10, each of the width and the depth of the first region 3a of the plating layer 3 and a width of one side of the second region 3b may be larger than or equal to the thickness of the protective film 8. As illustrated in FIG. 9, B1 denotes the width of the first region 3a, and B2 denotes the depth of the first region 3a. Furthermore, C1 and C2 denote widths of sides of the second region 3b, C1 denotes the width of one side of the second region 3b adjacent to B1, and C2 denotes the width of one side of the second region 3b adjacent to B2. As illustrated in FIGS. 9 and 10, A≤B1, B2, C1, and C2 may hold, where A denotes the thickness of the protective film 8. As illustrated in FIGS. 9 and 10, each of the width and the depth of the first region 3a of the plating layer 3 is preferably larger than the width of one side of the second region 3b adjacent to the first region 3a. The structure satisfying C1≤B1 and C2≤B2 can ensure the dimensions of the first region 3a on which solder is mounted. The thickness of the protective film 8 is, for example, approximately 10 μm.

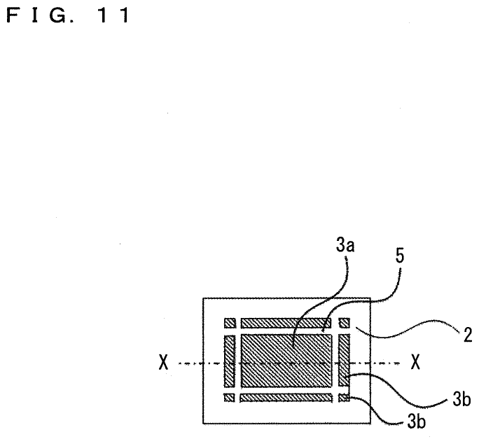

As illustrated in FIG. 11, spaces may be formed. As illustrated in FIG. 11, the shape of the second region 3b may be changed depending on the shape of the spaces.

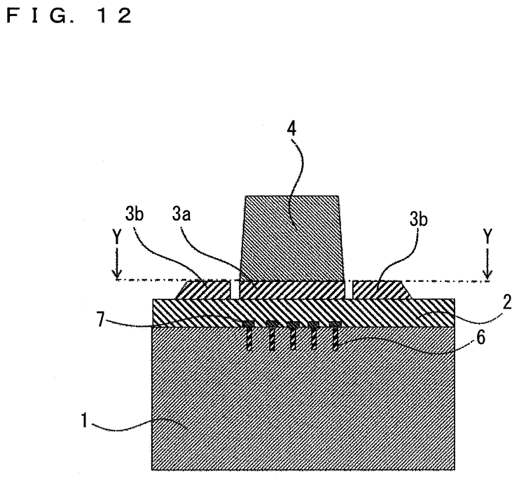

Gate electrodes 6 may be formed on the upper surface of the semiconductor substrate 1. As illustrated in FIG. 12, it is preferred to have a structure in which the gate electrodes 6 are formed on the upper surface of the semiconductor substrate 1 and immediately below the first region 3a and the gate electrodes 6 are not formed immediately below the second region 3b. Not forming the gate electrodes 6 immediately below the second region 3b allows the main current to flow only immediately below the first region 3a on which solder is mounted. Although FIG. 12 illustrates the gate electrodes 6 with a trench structure, the gate electrodes 6 may be gate electrodes with a planar structure. As illustrated in FIG. 12, the interlayer insulating film 7 may be formed on the upper surface of the gate electrodes 6.

### Embodiment 2

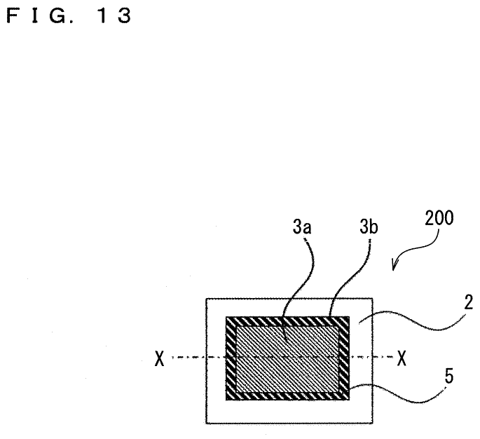

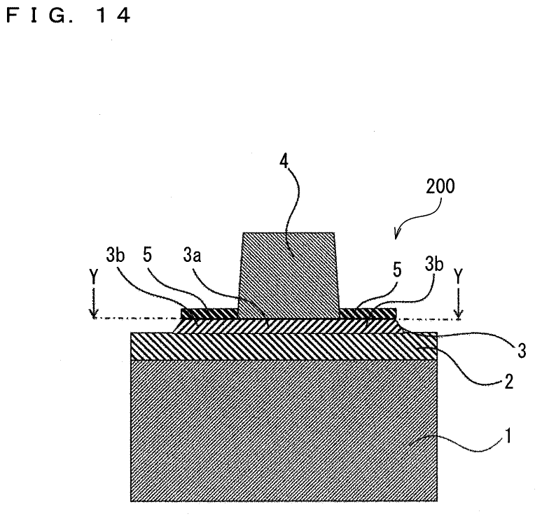

A semiconductor device 200 according to Embodiment 2 will be described with reference to FIGS. 13 and 14. FIG. 13 is a schematic plan view of the semiconductor device 200 according to Embodiment 2. FIG. 14 is a schematic cross-sectional view of the semiconductor device 200 according to Embodiment 2. FIG. 14 illustrates a cross section taken along an alternate long and short dashed line X-X in FIG. 13. FIG. 13 additionally illustrates the solder blocking portion 5 in a horizontal cross sectional view taken along an alternate long and short dashed line Y-Y in FIG. 14 for convenience of the description, and omits the illustration of the solder layer 4.

In the semiconductor device 200 according to Embodiment 2, the solder blocking portion 5 is an oxide film. As illustrated in FIGS. 13 and 14, the oxide film is formed on the second region 3b of the plating layer 3. Embodiment 2 differs from Embodiment 1 in that the solder blocking portion 5 is an oxide film and is formed on the second region 3b of the plating layer 3. Although the oxide film is formed across the entire second region 3b as illustrated in FIGS. 13 and 14 in Embodiment 2, an oxide film may be formed only in a region of the second region 3b closer to the first region 3a. For example, the oxide film may be formed to surround the first region 3a only in a region of the second region 3b closer to the first region 3a.

As illustrated in FIG. 13, the oxide film is preferably formed such that the center of the first region 3a matches the center of the entire plating layer 3. Although the oxide film is symmetrically formed with respect to the center of the entire plating layer 3 in FIG. 13, the oxide film need not be symmetrically formed. The oxide film has only to be formed on the second region 3b, and the formation position and the shape of the oxide film may be any. The width of the oxide film may be changed for each of the sides.

The semiconductor device 200 in Embodiment 2 is structured in the aforementioned manner. The structure of the plating layer 3 with the oxide film that is the solder blocking portion 5 can reduce occurrence of the triple point of the three layers of the plating layer 3, the resin layer, and the solder layer 4 on the electrode layer 2, and prevent a split in the electrode layer 2. This reason will be hereinafter described.

Forming the oxide film can block the solder supplied onto the first region 3a from flowing on the second region 3b from above the first region 3a. Since solder does not wet on the oxide film, the solder stays on the first region 3a without flowing on the second region 3b. Thus, the solder does not flow on the electrode layer 2. Consequently, even when the semiconductor device 200 is sealed by a sealing resin, it is possible to reduce occurrence of the triple point of the three layers of the plating layer 3, a resin layer containing the sealing resin, and the solder layer 4 on the electrode layer 2. This can prevent a split in the electrode layer 2.

Next, a method of manufacturing the semiconductor device 200 according to Embodiment 2 will be described. The method of manufacturing the semiconductor device 200 according to Embodiment 2 differs from that according to Embodiment 1 by the solder blocking portion formation step. The solder blocking portion formation step will be hereinafter described, and the other steps are identical to those according to Embodiment 1.

Embodiment 2 will describe an example method of forming an oxide film on the second region 3b of the plating layer 3, using the solder blocking portion 5 as the oxide film.

The example method of forming an oxide film will be described. First, a metal more highly-ionizable than a metal included in the plating layer 3 is applied to the second region 3b. Here, the metal included in the plating layer 3 is referred to as a first metal, and the metal more highly-ionizable than the metal included in the plating layer 3 is referred to as a second metal. When the first metal is Au, such as Li or Cu oxidized in the air is preferably the second metal, and the second metal is, for example, Al.

Next, the second metal is oxidized to form an oxide film. For example, exposing the second metal to the air may oxidize the second metal.

When the second metal is applied to the second region 3b, it is preferred that the second metal does not flow on the electrode layer 2 and stays on the second region 3b. When the second metal flows on the electrode layer 2, a triple point of three layers of an oxide film formed by oxidizing the second metal, the plating layer 3, and a sealing resin occurs on the electrode layer 2. When the second metal is applied to the second region 3b to prevent the second metal from flowing on the electrode layer 2, it is possible to prevent occurrence of the triple point of the three layers of the oxide film, the plating layer 3, and the sealing resin on the electrode layer 2.

With the aforementioned steps, the semiconductor device 200 is fabricated. As described above, the method of manufacturing the semiconductor device 200 according to Embodiment 2 includes the solder blocking portion formation step, and the solder blocking portion 5 is an oxide film. Forming the oxide film as the plating layer 3 can block the solder supplied onto the first region 3a from flowing on the second region 3b from above the first region 3a in the solder layer formation step, similarly to Embodiment 1. Since solder does not wet on the oxide film, the solder stays on the first region 3a without flowing on the second region 3b. Thus, the solder does not flow on the electrode layer 2. Thus, even when the semiconductor device 200 is sealed by the sealing resin, it is possible to reduce occurrence of the triple point of the three layers of the plating layer 3, the resin layer containing the sealing resin, and the solder layer 4 on the electrode layer 2. This can prevent a split in the electrode layer 2.

Furthermore, when the solder blocking portion 5 is an oxide film, the solder blocking portion 5 can be formed relatively easier than that according to Embodiment 1 in which the solder blocking portion 5 is a space.

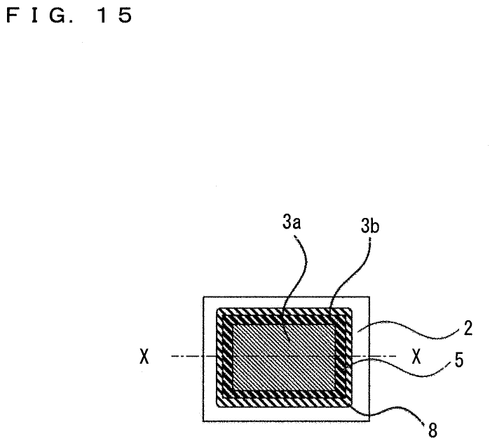

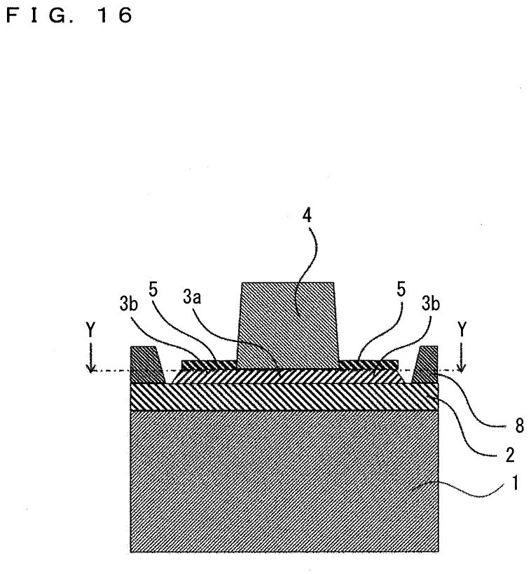

Next, modifications of Embodiment 2 will be described with reference to FIGS. 15 to 19. First, Modification 1 will be described with reference to FIGS. 15 and 16. FIG. 15 is a schematic plan view of a semiconductor device according to Modification 1. FIG. 16 is a schematic cross-sectional view of the semiconductor device according to Modification 1. FIG. 16 illustrates a cross-sectional view taken along an alternate long and short dashed line X-X in FIG. 15. FIGS. 15, 18, and 19 are plan views obtained by adding the solder blocking portion 5 to respective horizontal cross sectional views corresponding to the plan views. Each of the horizontal cross sectional views has a cross section taken along an alternate long and short dashed line Y-Y in the cross-sectional view, similarly to FIG. 13.

As illustrated in FIGS. 15 and 16, the protective film 8 may be further formed on the upper surface of the electrode layer 2 to surround the outer periphery of the plating layer 3. As illustrated in FIG. 15, the protective film 8 may be formed to surround the outer periphery of the second region 3b of the plating layer 3.

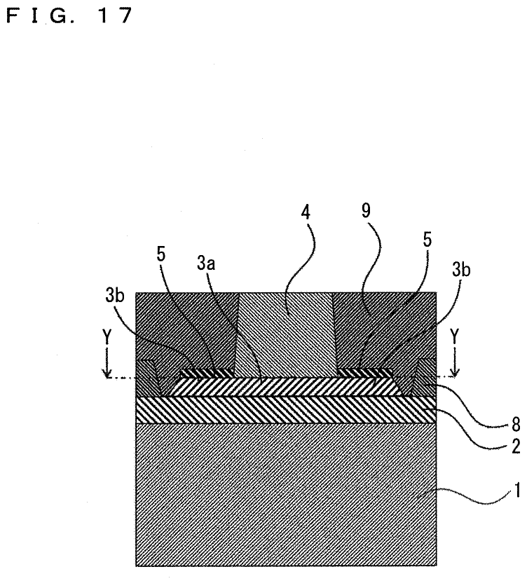

Next, Modification 2 will be described with reference to FIG. 17. FIG. 17 is a schematic cross-sectional view of the semiconductor device according to Modification 2. Modification 2 assumes that a semiconductor device is sealed by a sealing resin. As illustrated in FIG. 17, the semiconductor device may be sealed by the sealing resin 9, similarly to Modification 2 of Embodiment 1.

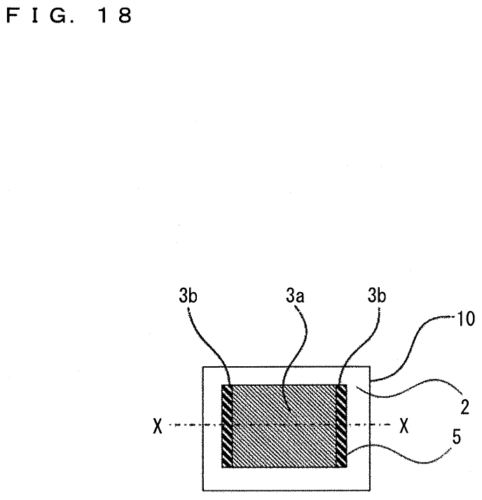

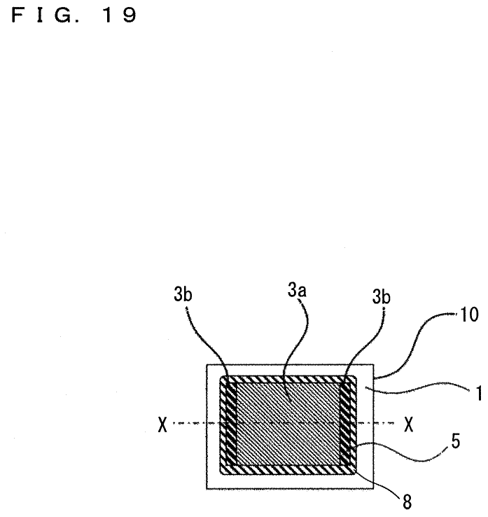

Next, Modification 3 will be described with reference to FIGS. 18 and 19. FIGS. 18 and 19 are schematic plan views of a semiconductor device according to Modification 3. The cross-sectional view taken along an alternate long and short dashed line X-X in FIG. 18 is identical to that in FIG. 14. The cross-sectional view taken along an alternate long and short dashed line X-X in FIG. 19 is identical to that in FIG. 16. As illustrated in FIG. 18, when the semiconductor chip 10 is rectangular in a plan view, an oxide film may be formed only in regions of the plating layer 3 which are located on the short sides of the semiconductor chip 10. When the semiconductor chip 10 is rectangular, it is known that allowing solder to flow through the short sides of the semiconductor chip 10 more than the long sides of the semiconductor chip 10 tends to cause splits in the electrode layer 2. Here, forming the oxide films only in the regions of the plating layer 3 which are located on the short sides of the semiconductor chip 10 can reduce occurrence of the triple point on the electrode layer 2 on the short sides of the semiconductor chip 10 where splits easily occur, and can prevent a split in the electrode layer 2. Moreover, the structure of Modification 3 can increase the area of the first region 3a more than that of the structure according to Embodiment 2. This can widen a region on which solder is mounted, and improve the bonding strength.

As illustrated in FIG. 19, the protective film 8 may be formed in addition to the structure of Modification 3, similarly to Modification 1. As illustrated in FIG. 19, the protective film 8 may be formed to surround an outer periphery of the entire plating layer 3 including the oxide films.

Furthermore, the sealing resin 9 may be formed in addition to the structure of Modification 3, similarly to Modification 2.

Each of the width and the depth of the first region 3a of the plating layer 3 and one side of the second region 3b may be larger than or equal to the thickness of the protective film 8, similarly to Modification 4 of Embodiment 1. Each of the width and the depth of the first region 3a of the plating layer 3 is preferably larger than the width of one side of the second region 3b adjacent to the first region 3a. This can ensure the dimensions of the first region 3a on which solder is mounted.

The structures described in Embodiments are examples of the details of the present disclosure, and can be combined with other known arts. Furthermore, Embodiments and modifications can be combined. A part of the structures can be omitted or changed without departing from the spirit and scope of the disclosure.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device sealed by a sealing resin, the semiconductor device comprising:
a semiconductor substrate;
an electrode layer disposed on an upper surface of the semiconductor substrate;
a plating layer disposed on an upper surface of the electrode layer, the plating layer including a first region, and a second region outside of the first region in a plan view;
a solder layer disposed on the first region of the plating layer; and
a solder blocking portion formed on the plating layer, the solder blocking portion blocking solder from flowing on the second region from above the first region.

2. The semiconductor device according to claim 1,
wherein the solder blocking portion is a space between the first region and the second region.

3. The semiconductor device according to claim 1,
wherein the solder blocking portion is an oxide film formed on the second region of the plating layer.

4. The semiconductor device according to claim 1,
wherein a semiconductor chip is rectangular in a plan view, and
the solder blocking portion is formed only in a region of the plating layer which is located on a short side of the semiconductor chip.

5. The semiconductor device according to claim 1, further comprising
a protective film on the upper surface of the electrode layer to surround an outer periphery of the plating layer.

6. The semiconductor device according to claim 5,
wherein each of a width and a depth of the first region of the plating layer and a width of one side of the second region is larger than or equal to a thickness of the protective film in a plan view.

7. The semiconductor device according to claim 2,
wherein the space is a crack that splits the plating layer into the first region and the second region.

8. The semiconductor device according to claim 2,
wherein a side surface of the first region of side surfaces of the first region and the second region that form the space is vertical to the upper surface of the electrode layer.

9. The semiconductor device according to claim 2,
wherein the sealing resin is not charged into the space.

10. The semiconductor device according to claim 1,
wherein a gate electrode is disposed on the upper surface of the semiconductor substrate and immediately below the first region, and the gate electrode is not disposed immediately below the second region.

11. The semiconductor device according to claim 1,
wherein the electrode layer is made of an aluminum alloy.

12. The semiconductor device according to claim 1,
wherein the semiconductor substrate is made of silicon carbide.

13. A method of manufacturing a semiconductor device sealed by a sealing resin, the method comprising:
an electrode layer formation step of forming an electrode layer on an upper surface of a semiconductor substrate;
a plating layer formation step of forming a plating layer on an upper surface of the electrode layer, the plating layer including a first region, and a second region outside of the first region in a plan view;
a solder blocking portion formation step of forming a solder blocking portion in the plating layer, the solder blocking portion blocking solder from flowing on the second region from above the first region; and
a solder layer formation step of supplying the solder onto the first region to form a solder layer.

14. The method according to claim 13,
wherein the solder blocking portion is a space, and
the space is formed between the first region and the second region in the solder blocking portion formation step.

15. The method according to claim 14,
wherein the space is formed by splitting the plating layer into the first region and the second region in the solder blocking portion formation step.

16. The method according to claim 13,
wherein the solder blocking portion is an oxide film, and
the oxide film is formed on the second region in the solder blocking portion formation step.

17. The method according to claim 16,
wherein the oxide film is formed by applying a metal more highly-ionizable than a metal included in the plating layer to the second region and oxidizing the more highly-ionizable metal in the solder blocking portion formation step.
